(19) United States
(12) Patent Application Publication
(10) Pub. No.: US 2017/0229331 A1
(43) Pub. Date: Aug. 10, 2017

(54) TEMPERATURE SENSING SYSTEM FOR ROTATABLE WAFER SUPPORT ASSEMBLY

(71) Applicant: Watlow Electric Manufacturing Company, St. Louis, MO (US)

(72) Inventors: Mohammad Nosrati, Redwood City, CA (US); Timothy B. Tompkins, San Jose, CA (US)

(73) Assignee: Watlow Electric Manufacturing Company, St. Louis, MO (US)

(21) Appl. No.: 15/427,701

(22) Filed: Feb. 8, 2017

Related U.S. Application Data
(60) Provisional application No. 62/292,614, filed on Feb. 8, 2016.

(51) Int. Cl. H01L 21/67; H01L 21/687

(52) U.S. Cl. CPC H01L 21/67248; H01L 21/68792; H01L 21/67103

(57) ABSTRACT

A semiconductor processing apparatus includes a wafer support assembly, a temperature sensor integrated in the wafer support assembly for measuring a temperature of the wafer support assembly, and a signal transmission device that wirelessly transmits a signal relating to a temperature measurement obtained by the temperature sensor to an external control module.

### CROSS-REFERENCE TO RELATED APPLICATIONS

This application claims the benefit of U.S. provisional application Ser. No. 62/292,614, filed on Feb. 8, 2016. The disclosure of the above application is incorporated herein by reference in its entirety.

### FIELD

The present disclosure relates to semiconductor processing apparatuses, and more particularly to temperature sensing systems for the semiconductor processing apparatuses.

### BACKGROUND

The statements in this section merely provide background information related to the present disclosure and may not constitute prior art.

Semiconductor processing involves various process steps performed on wafers in a processing chamber. In some of the processing steps, heaters are used to heat a wafer to be processed at an elevated temperature, e.g., in the range of 300° C.-1100° C. The wafer is heated by placing the wafer on a heated wafer support portion. To heat the wafer support portion, the heater may be formed as an integral part of the wafer support portion, or disposed under the wafer support portion. In some processes, such as a film deposition process, the heated wafer support portion need to be rotated. Therefore, the heater may be configured to be rotatable with the wafer support portion or remain stationary when the wafer support portion rotates

Where the heater is provided under the wafer support portion, it is difficult to control the temperature of the wafer disposed on a rotating wafer support portion. First, the heat is transferred from the heater to the rotating wafer support portion primarily through radiation in a vacuum/low pressure environment of the processing chamber. A significant portion of the heat from the heater is lost to the surrounding environment. Therefore, it is difficult to estimate how much heat is needed from the heater to achieve a desired temperature change in the wafer. Second, the rotating movement of the wafer support portion makes direct temperature sensing difficult. Optical sensing/non-contact devices such as pyrometers are typically used to measure the surface temperature of the wafer at one or a few locations when the wafer rotates with the wafer support portion. The remote-temperature sensing typically does not provide desired temperature measurements across the wafer.

### SUMMARY

In one form of the present disclosure, a semiconductor processing apparatus includes a wafer support assembly, a temperature sensor integrated in the wafer support assembly for measuring a temperature of the wafer support assembly, and a signal transmission device that wirelessly transmits a signal relating to a temperature measurement obtained by the temperature sensor to an external control module.

In another form, a temperature sensing system includes a temperature sensor for obtaining temperature information, and a WiFi connectivity module for wirelessly transmitting the temperature information obtained by the temperature sensor to a control module.

In still another form, a semiconductor processing system includes a processing chamber, a wafer support assembly, a heater, a heater control module for controlling the hater, a temperature sensor, and a WiFi connectivity module. The wafer support assembly includes a wafer support portion disposed inside the processing chamber and a shaft connected to the wafer support portion and extending through a wall of the processing chamber. The heater heats the wafer support portion. The temperature sensor is integrated in the wafer support portion. The WiFi connectivity module is electrically connected to the temperature sensor for wirelessly transmitting a signal relating to a temperature measurement obtained by the temperature sensor to the heater control module.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a cross-sectional view of a semiconductor processing apparatus incorporating a temperature sensing system constructed in accordance with the teachings of the present disclosure; and

FIG. 2 is a block diagram of a temperature sensing system constructed in accordance with the teachings of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses.

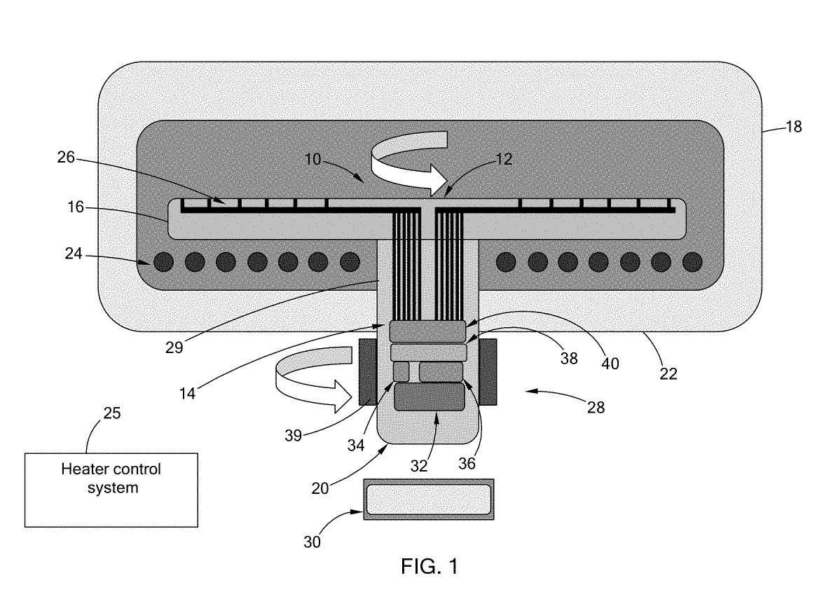

Referring to FIG. 1, a semiconductor processing apparatus according to the disclosure of the present application is generally indicated by reference 10. The semiconductor processing apparatus 10 includes a wafer support assembly 12, and a temperature sensing system 14 integrated in the wafer support assembly 12. The wafer support assembly 12 includes a wafer support portion 16 disposed in a semiconductor processing chamber 18 and a shaft 20 connected to the wafer support portion 16 and extending through a wall 22 of the semiconductor processing chamber 18. The wafer support portion 16 may be a susceptor, an electrostatic chuck or any support means that can support a wafer to be processed thereon. The shaft 20 is connected to an external rotating means/device (not shown) outside the semiconductor processing chamber 18. The external rotating device drives the wafer support assembly 12 to rotate in the semiconductor processing chamber 18.

The semiconductor processing apparatus 10 further includes a heater 24 disposed under the wafer support portion 16 to heat the wafer support portion 16 and the wafer (not shown) disposed thereon. The heater 24 is controlled by a heater control system 25 provided outside the processing chamber 18. The heater 24 may be a tubular heater.

The temperature sensing system 14 includes a plurality of temperature sensors 26 integrated in the wafer support portion 16, a sensing control unit 28 connected to the temperature sensors 26 through a plurality of wires 29. The sensing control unit 28 includes an inductive power supply charging module 30, a DC power supply 32, an interactive WiFi connectivity module 34, an operating system electronic module 36, an access electronic module 38, and a scanning sensing electronic input module 40. Among the various modules of the sensing control unit 28, only the inductive power supply charging module 30 is disposed outside the shaft 20 and is stationary, whereas the remaining modules 32, 34, 36, 38, 40 are disposed inside the shaft 20 at portions outside the processing chamber 18.

In one form, the sensing electronic input module 40 accepts low voltage or current inputs from the temperature sensors 26. The sensing electronic input module 40 input types, cold-junction-compensation, scales, ranges, error reporting, linearization, and calibration offset adjustments are independent per input channel. In one form, each sensing electronic input module 40 can accept up to 16 inputs and make the conditioned and buffered values available to the other modules on the back-plane bus at a 10 Hz update rate. It should be understood that any number of inputs and different update rates may be provided while remaining within the scope of the present disclosure.

The operating system electronic module 36 is an option that is typically used in PLC (Programmable Logic Controller) systems, but is not generally used in its generic form in a distributed-processor system. Typical functions performed may include data acquisition and distribution scheduling, math processing, error and exception handling, HMI (Human Machine Interface) driving, start-up and shut-down management, local-remote access management, local data logging, and multiple communications port access, among others.

The access electronic module 38 in one form is a two-port communications translator that sits (logically, not physically) between a local back-plane data bus and an external “field bus” that communicates bi-directionally with the host computer system for control and data acquisition. Some examples of field bus options would be Modbus serial, Modbus TCP (EtherNET), EtherCAT, DeviceNet, or Profibus. In addition, the access electronic module 38 can hold a copy of the configuration file for every other module on the back-plane bus, to be used for quick and accurate software configuration of replacement modules.

The DC power supply 32 is integrated into the shaft 20 to provide power to the interactive WiFi connectivity module 34, the operating system electronic module 36, the access electronic module 38, and the scanning sensing electronic input module 40 integrated in the shaft 20. The inductive power supply charging module 30 charges the DC power supply 32 by induction.

In still another form, a cooling device or loop 39 is disposed around the shaft 20. This cooling device 39 may take on any number of forms, including a sleeve provided with a cooling fluid, which may be separate or integrated within the shaft 20.

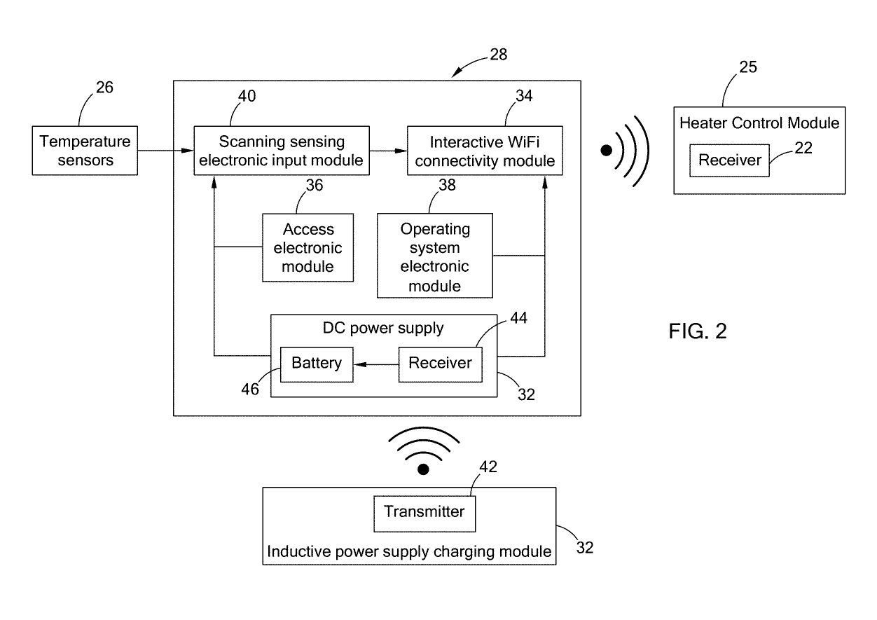

Referring to FIG. 2, the inductive power supply charging module 30 may include a transmitter 42. The DC power supply 32 may include a receiver 44 and a battery 46. As an example, the transmitter 42 and the receiver 44 may be in the form of a first coil and a second coil, respectively. The inductive power supply charging module 30 is disposed proximate the DC power supply 32. The inductive power supply charging module 30 may constantly or periodically activate the first coil, which then creates a magnetic field to induce an electric current in the second coil in the DC power supply 32 to charge the battery 46. As a result, the battery 46 of the DC power supply 32 can be constantly or periodically charged and supply power to the various modules 34, 36, 38 and 40 integrated in the wafer support assembly 12. Alternatively, the power of the battery 46 of the DC power supply 32 may be monitored so that the inductive power supply charging module 30 activates the transmitter 42 to charge the battery 46 when the power of the battery 46 is reduced to a threshold.

The temperature sensors 26 may take any form known in the art, such as thermocouples and are integrated in the wafer support portion 16 to directly measure the temperature of the wafer support portion 16. Therefore, the temperature of the wafer disposed on the wafer support portion 16 can be more accurately measured. The temperature sensors 26 may transmit signals to the scanning sensing electronic input module 40 for signal processing to determine a temperature of the wafer. The access electronic module 36 determines the locations of the temperature sensors that transmit the signals. The operating system electronic module 38 converts the signals relating to the temperature and the signals relating to the locations of the temperature sensors into a wireless packet. The interactive WiFi connectivity module 34 transmits the wireless packet to the heater control module 26 which includes a receiver 22 to receive the wireless packet containing temperature measurement information. The heater control module 26 then controls and adjusts the heat output of the heater 24 based on the temperature measurement information and a desired temperature profile on the wafer.

In the temperature sensing system 14 of the present application, direct temperature sensing is possible by integrating the temperature sensors 26 in the rotating wafer support assembly and by wirelessly transmitting the temperature measurement information to an external heater control module 26. Therefore, the temperature sensing system 14 can more accurately measure the temperature of the wafer. No wirings are used to transmit the temperature measurement signals to an external control module 26.

It should be noted that the disclosure is not limited to the forms described and illustrated as examples. A large variety of modifications have been described and more are part of the knowledge of the person skilled in the art. These and further modifications as well as any replacement by technical equivalents may be added to the description and figures, without leaving the scope of the protection of the disclosure and of the present patent.

What is claimed is:

1. A semiconductor processing apparatus, comprising:
a wafer support assembly;
a temperature sensor integrated in the wafer support assembly for measuring a temperature of the wafer support assembly; and
a signal transmission device that wirelessly transmits a signal relating to a temperature measurement obtained by the temperature sensor to an external control module.

2. The semiconductor processing apparatus according to claim 1, wherein the signal transmission device is integrated in the wafer support assembly.

3. The semiconductor processing apparatus according to claim 1, wherein the signal transmission device includes an interactive WiFi connectivity module.

4. The semiconductor processing unit according to claim 1, further comprising a DC power supply integrated in the wafer support assembly, and an inductive power supply charging module disposed outside the wafer support assembly.

5. The semiconductor processing unit according to claim 4, wherein the inductive power supply charging module includes a first coil, and the DC power supply includes a second coil, the first coil generating magnetic field to induce an electric current in the second coil.

6. The semiconductor processing unit according to claim 1, further comprising a sensing electronic input module integrated in the wafer support assembly.

7. The semiconductor processing unit according to claim 1, wherein the wafer support assembly includes a wafer support portion and a shaft connected to the wafer support portion, wherein the temperature sensor is disposed in the wafer support portion, and the signal transmission device is disposed in the shaft.

8. The semiconductor processing apparatus according to claim 7, further comprising a heater disposed under the wafer support portion of the wafer support assembly.

9. The semiconductor processing apparatus according to claim 7, wherein the wafer support assembly is rotatable.

10. The semiconductor processing apparatus according to claim 1, wherein the external control module is a heater control module that controls a heater based on the temperature measurement.

11. A temperature sensing system comprising:
a temperature sensor for obtaining temperature information; and
a WiFi connectivity module for wirelessly transmitting a signal relating to the temperature information obtained by the temperature sensor to an external control module, wherein the temperature sensing system is part of a rotating device.

12. The temperature sensing system according to claim 11, further comprising a power source to supply power to the WiFi connectivity module, wherein the power source includes a DC power supply and an inductive power supply charging module that charges the DC power supply through induction.

13. The temperature sensing system according to claim 12, wherein the inductive power supply charging module includes a first coil, and the DC power supply includes a second coil, wherein the first coil generates a magnetic field that induces an electric current in the second coil.

14. The temperature sensing system according to claim 11, further comprising a scanning sensing electronic input module.

15. The temperature sensing system according to claim 11, further comprising an access electronic module.

16. The temperature sensing system according to claim 11, further comprising an operating system electronic module.

17. A semiconductor processing system, comprising:
a processing chamber;
a rotatable wafer support assembly including a wafer support portion disposed inside the processing chamber and a shaft connected to the wafer support portion and extending through a wall of the processing chamber;
a heater for heating the wafer support portion;
a heater control module for controlling the heater;
a temperature sensor integrated in the wafer support portion; and
a WiFi connectivity module electrically connected to the temperature sensor and wirelessly transmitting a signal relating to a temperature measurement obtained by the temperature sensor to the heater control module.

18. The semiconductor processing system according to claim 17, wherein the heater control module includes a receiver for receiving the signal from the WiFi connectivity module.

19. The semiconductor processing system according to claim 17, further comprising a DC power supply disposed in the shaft and an inductive power supply charging module disposed proximate the DC power supply and outside the shaft.

20. The semiconductor processing system according to claim 17 further comprising a scanning sensing electronic input module, an access electronic module, and an operating system electronic module.

21. The semiconductor processing system according to claim 17 further comprising a cooling device disposed around the shaft.
